(19) United States
(12) Patent Application Publication
(10) Pub. No.: US 2026/0129764 A1
(43) Pub. Date: May 7, 2026

(54) REMOVAL APPARATUS AND METHOD USING THE SAME

(71) Applicant: Aivres Systems Inc., Fremont, CA (US)

(72) Inventor: Cheng Hong LAI, New Taipei City (TW)

(73) Assignee: Aivres Systems Inc., Fremont, CA (US)

(21) Appl. No.: 19/435,935

(22) Filed: Dec. 30, 2025

(51) Int. Cl. H05K 3/00

(52) U.S. Cl. CPC H05K 3/0044; H05K 2203/025

(57) ABSTRACT

A removal apparatus is provided. The removal apparatus includes a support member, a substance-removing member, and/or a spring member. The substance-removing member includes a handle portion, a first shaft portion, and a second shaft portion. The first shaft portion comprises a first end connecting to the handle portion, and a second end connecting to the second shaft portion. The substance-removing member further includes a substance-removing assembly secured (or removably attached) to the second shaft portion. A diameter of the spring member is greater than a diameter of the second shaft portion and is less than a diameter of the first shaft portion. The substance-removing assembly includes a substance-removing head for removing substance(s). For example, the substance-removing head can be applied to remove a portion of a solder mask and/or a portion of a conductive element (e.g., signal trace or plated via) covered by the solder mask.

### TECHNICAL FIELD

The present disclosure relates generally to a removal apparatus and method.

### BACKGROUND

A printed circuit board (PCB) is commonly used in electronic products and systems to hold and connect components (e.g., integrated circuits, capacitors, resistors, inductors, etc.) of an electrical circuit. The PCB often includes a substrate and a conductive layer (e.g., copper foil) that is disposed on the substrate and etched to form conductive traces (or patterns) for connecting the components (which are often soldered to the PCB). The PCB often further includes a protective layer (e.g., solder mask) disposed on the conductive layer, to protect the conductive layer.

During manufacturing and maintenance of a PCB, conductive trace(s) covered by the protective layer often need to be exposed, cut, or replaced, in order to test or modify the electrical circuit. A precision knife, utility knife, or scraper is often used to perform such tasks. However, applying these tools for PCB substance removal is difficult. When accessing or modifying a trace using one of the existing tools, a person can easily damage adjacent trace(s) or the structure of the PCB, and such damage to the PCB is typically irreversible.

### SUMMARY

Techniques are described herein for precise substance removal from a PCB (or any other applicable board or structures), to test, modify, or cut one or more elements (e.g., conductive elements such as a conductive trace or a plated via) of the PCB.

According to one aspect of the present disclosure, a removal apparatus is provided. The removal apparatus includes a support member, and a substance-removing member comprising a substance-removing head. In some embodiments, a bottom portion of the support member includes a through-hole that allows the substance-removing head to pass through.

In some embodiments, the substance-removing member includes a substance-removing assembly, and the substance-removing assembly includes a body portion and the substance-removing head, where the substance-removing head is removably attached to the body portion.

In some embodiments, a diameter of the substance-removing head is approximately 2-10 mils. The diameter or other dimensions of the substance-removing head can be configured or determined based on dimensions of the one or more elements (of the PCB) that are to be cut, modified, or tested, such that precise substance removal is realized.

In some embodiments, the substance-removing member further includes a first shaft portion and a second shaft portion, where a first end of the second shaft portion is connected to the body portion of the substance-removing assembly, and a second end of the second shaft portion that is opposite to the first end is connected to the first shaft portion. In some embodiments, a diameter of the first shaft portion is greater than a diameter of the second shaft portion.

In some embodiments, the substance-removing member further comprises an upper handle fixed to the first shaft portion. One or more forces can be applied to the upper handle to control the substance-removing head of the removal apparatus, so as to perform substance removal.

In some embodiments, the removal apparatus further comprises a spring member, where a diameter of the spring member is greater than a diameter of the second shaft portion, and the diameter of the spring member is less than a diameter of the first shaft portion.

In some embodiments, the removal apparatus further includes an additional substance-removing head for removably attachment to the body portion of the substance-removing assembly, where a diameter (or other dimension) of the additional substance-removing head is different from a diameter (or other dimension) of the substance-removing head. This allows the removal apparatus to be applied to remove substance(s) from different components of the PCB (or other applicable board or structure).

In some embodiments, a dimension of the additional substance-removing head is determined based on an inner diameter and an outer diameter of a via (e.g., a plated via) of the PCB.

In some embodiments, a dimension of the substance-removing head is determined based on a width of a conductive trace of the PCB.

In some embodiments, the support member includes a support body and a plurality of support legs fixedly attached to the support body. In some embodiments, a base of a support leg from the plurality of support legs comprises a flat bottom surface.

In some embodiments, the support body of the support member is hollow and comprises an opening for insertion of the substance-removing member. In some embodiments, a diameter of the opening of the support member is greater than a diameter of a first shaft portion of the substance-removing member.

In some embodiments, the support member is made of a rigid material.

According to one aspect of the present disclosure, a system is provided. The system includes: a removal apparatus; and a driving unit to drive the removal apparatus. The removal apparatus includes: a spring member, a support member to hold the spring member, and a substance-removing member comprising a substance-removing head. A bottom portion of the support member comprises a through-hole that allows the substance-removing head to pass through.

According to one aspect of the present disclosure, a method is provided. The method includes: determining a to-be-exposed area of a conductive element of a printed circuit board (PCB), the to-be-exposed area of the conductive element being covered by a protective layer of the PCB; placing a removal apparatus at a first location with respect to the to-be-exposed area of the conductive element; contacting a substance-removing head of the removal apparatus with a to-be-removed portion of the protective layer that covers the to-be-exposed area of the conductive element; and rotating the substance-removing head of the removal apparatus so that the to-be-removed portion of the protective layer is removed to expose the to-be-exposed area of the conductive element.

In some embodiments, the conductive element is a conductive trace, and the method includes: further rotating the substance-removing head of the removal apparatus, thereby cutting the conductive trace.

In some embodiments, further rotating the substance-removing head of the removal apparatus includes: placing the removal apparatus at a second location different from the first location; contacting the substance-removing head of the removal apparatus with an additional to-be-removed portion of the protective layer; and rotating the substance-removing head of the removal apparatus, thereby removing the additional to-be-removed portion of the protective layer.

In some embodiments, the method further includes: selecting, based on one or more dimensions of the conductive element, the substance-removing head from a plurality of substance-removing heads for the removal apparatus, prior to placing the removal apparatus with respect to the to-be-exposed area of the conductive element.

### BRIEF DESCRIPTION OF THE DRAWINGS

Systems and methods of the present disclosure are described in detail below with reference to the attached drawing figures, wherein:

FIG. 1 illustrates a perspective view of an example printed circuit board (PCB), according to one or more embodiments of the present disclosure.

FIG. 2 illustrates a scenario where a precision knife is applied to modify a conductive trace of an example PCB, according to one or more embodiments of the present disclosure.

FIG. 3A illustrates an example removal apparatus, according to one or more embodiments of the present disclosure.

FIG. 3B illustrates an exploded view of an example removal apparatus, according to one or more embodiments of the present disclosure.

FIG. 3C illustrates two non-limiting examples of substance-removing heads, according to one or more embodiments of the present disclosure.

FIG. 4A illustrates a scenario where an example removal apparatus is placed proximately to a conductive trace of a PCB, according to one or more embodiments of the present disclosure.

FIG. 4B illustrates an example removal apparatus in contact with a to-be-removed portion of the PCB.

FIG. 4C illustrates exposure of an area of a conductive trace, according to one or more embodiments of the present disclosure.

FIG. 4D illustrates a cut of a conductive trace of a PCB, according to one or more embodiments of the present disclosure.

FIG. 5A illustrates an example of a removal apparatus placed proximately to a PCB, according to one or more embodiments of the present disclosure.

FIG. 5B illustrates an example of a removal apparatus where a substance-removing head is in contact with a to-be-removed portion of a PCB that includes a plated via in FIG. 5A.

FIG. 5C illustrates exposure of an area of a plated via, according to one or more embodiments of the present disclosure.

FIG. 6 illustrates a method for exposing and/or modifying an element (e.g., a conductive trace) of a PCB, according to one or more embodiments of the present disclosure.

FIG. 7 illustrates an example system, according to one or more embodiments of the present disclosure.

### DETAILED DESCRIPTION

The following detailed description is exemplary in nature and is not intended to limit the disclosure or the application and uses of the described embodiments. Furthermore, there is no intention to be bound by any expressed or implied theory presented in the preceding background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

Apparatus, systems, and methods are disclosed herein that relate to removing one or more types of substances from a printed circuit board (PCB) that holds and connects components (e.g., capacitors, inductors, etc.) of an electrical circuit.

In various embodiments, a removal apparatus is placed on a protective layer of the PCB, with a substance-removing head of the removal apparatus being directed to a to-be-removed portion of the protective layer that covers, for example, a to-be-tested area (sometimes also referred to as “to-be-exposed area”) of a conductive element of the PCB. A first force can be applied to a handle portion of the removal apparatus, for the substance-removing head to be in contact with the to-be-removed portion of the protective layer, and a second force can be applied to cause the substance-removing head to rotate, thereby removing the to-be-removed portion of the protective layer. This way, the to-be-tested area of the conductive element can be exposed, e.g., for electrical test(s) which determines an operating condition of the electrical circuit.

In some embodiments, the conductive element is a plated via (e.g., a through-hole via or a blind via plated with a conductive material). In some embodiments, the conductive element is a conductive trace (e.g., copper trace), and the substance-removing head can be further rotated to cut the conductive trace, for subsequent modification (e.g., re-wiring) of the electrical circuit. In some embodiments, a driving unit can be coupled (e.g., electrically coupled) to the removal apparatus to push and/or rotate the substance-removing head of the removal apparatus.

In some embodiments, the removal apparatus can include a plurality of substance-removing heads. Depending on one or more dimensions (e.g., width) of the conductive element (e.g., a plated via or a conductive trace), the substance-removing head having a diameter approximately the same as the width of the conductive trace can be selected from the plurality of substance-removing heads. The selected substance-removing head can be removably attached to a body portion of the removal apparatus, to remove substance(s) as discussed above.

By utilizing apparatus and systems described above, a user can precisely remove a target component of the PCB, without damaging adjacent components. Embodiments thus mitigate against causing irreversible damages to the PCB, and allow even users with little experience to test or modify the PCB. The apparatus and systems of the present disclosure cost relatively low to manufacture, are easy to assemble and convenient to use. They also facilitate users of PCBs to perform electrical testing and circuit modification during the development and testing stages of PCBs.

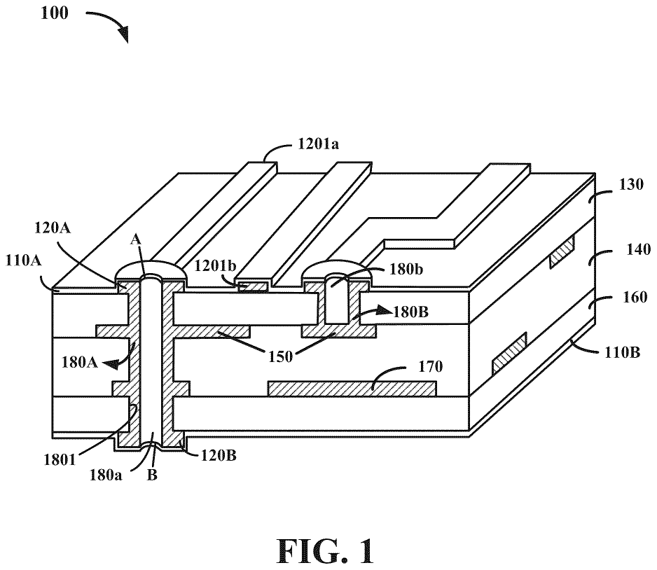

FIG. 1 is a simplified diagram illustrating a perspective view of an example printed circuit board (PCB) 100 that shows one or more traces (e.g., conductive traces) and/or one or more plated vias, according to one or more embodiments of the present disclosure. As shown in FIG. 1, the PCB 100 may have a multi-layer structure. The multi-layer structure can include one or more surface conductive layers, one or more protective layers each protecting a corresponding surface conductive layer, one or more insulating layers, one or more inner conductive layers, and/or other layers (e.g., substrate layer, binding layer which may also be referred to as “prepreg layer”, etc.). Descriptions of the multi-layer structure here are not intended to be limiting.

As a non-limiting example illustrated in FIG. 1, the PCB 100 can include a first protective layer 110A and a first surface conductive layer 120A, where the first protective layer 110A is disposed on the first surface conductive layer 120A to protect the first surface conductive layer 120A. The first surface conductive layer 120A can include, for instance, one or more conductive traces (also referred to as “signal traces”, see “1201a” or “1201b” as an example). The one or more conductive traces (e.g., 1201a and 1201b) may be, for example, formed by etching (or patterning) the first surface conductive layer 120A. The first surface conductive layer 120A may be, for instance, a copper foil or other suitable conductive material. For example, the one or more conductive traces 1201 can include a copper trace configured to carry an electrical signal. The first protective layer 110A may be disposed on the first surface conductive layer 120A, to prevent oxidation of the one or more conductive traces 1201, to prevent short circuits, and to prevent solder from bridging between adjacent conductive traces (e.g., 1201a and 1201b) or flowing into unintended areas. In some embodiments, the first protective layer 110A can include a solder mask.

In some embodiments, the PCB 100 further includes a first insulating layer 130. The first surface conductive layer 120A can be disposed on the first insulating layer 130. In some embodiments, the PCB 100 further includes a second insulating layer 140 and/or a first inner conductive layer 150 sandwiched between the first insulating layer 130 and the second insulating layer 140. In some embodiments, the PCB 100 further includes a third insulating layer 160 and/or a second inner conductive layer 170 sandwiched between the second insulating layer 140 and the third insulating layer 160.

In some embodiments, the PCB 100 further includes a second surface conductive layer 120B and a second protective layer 110B to protect the second surface conductive layer 120B. The second surface conductive layer 120B can include, for instance, one or more conductive traces (not illustrated in FIG. 1) formed, e.g., by etching the second surface conductive layer 120B. The second surface conductive layer 120B can be, for instance, a copper foil (or can be made of one or more other conductive materials). The second protective layer 110B may be disposed to cover the second surface conductive layer 120B, thereby preventing oxidation of the one or more conductive traces (or other conductive elements) of the second surface conductive layer 120B, preventing short circuits, and preventing solder from bridging between adjacent conductive traces or flowing into unintended areas. In some embodiments, the second protective layer 110B can include a solder mask.

In some embodiments, referring to FIG. 1, the PCB 100 can include a plurality of vias (sometimes referred to as “via holes”). One or more vias from the plurality of vias may be formed via a mechanical drilling process, a laser drilling process, a wet etching process, a dry etching process, or any applicable process forming a hole (e.g., a through-hole) within the PCB 100. One or more vias from the plurality of vias can each have a substantially vertical sidewall (e.g., 1801) be covered or plated with a conductive material, to provide electrical connection between different layers. For example, given a via from the plurality of vias, a side wall of the via can be plated with a conductive material (e.g., copper) to electrically connect two or more layers (e.g., the first surface conductive layer 120A and the first inner conductive layer 150) of the PCB 100. In some embodiments, the sidewall of the via can be vertical, tapered, or with other profile, depending on the process used to form the via.

The plurality of vias can include, for instance, a through-hole via 180a that runs through the PCB 100. Additionally, or alternatively, the plurality of vias can include, for instance, a blind via 180b that runs through a portion of the different layers of the PCB 100. The through-hole via 180a may run through the PCB 100 and be plated to form a plated through-hole via 180A that electrically connects the first surface conductive layer 120A with the second surface conductive layer 120B. For example, one or more conductive traces (e.g., 1201a) of the first surface conductive layer 120A can be electrically connected to one or more conductive traces of the second surface conductive layer 120B, through the plated through-hole via 180A. In some embodiments, the plated through-hole via 180A can electrically connect the first surface conductive layer 120A (and the second surface conductive layer 120B) with one or more inner conductive layers. For example, referring to FIG. 1, the plated through-hole via 180A electrically connects the first surface conductive layer 120A (and the second surface conductive layer 120B) with the first inner conductive layer 150 and/or the second inner conductive layer 170. The blind via 180b, for instance, can be plated to form a plated blind via 180B, and the plated blind via 180B can be applied to electrically connect the first surface conductive layer 120A (or the second surface conductive layer 120B) with one or more inner conductive layers. For example, referring to FIG. 1, the plated blind via 180B can electrically connect the first surface conductive layer 120A with the first inner conductive layer 150.

In some embodiments, a via (or a via having an inner sidewall plated with a conductive material, i.e., “a plated via”) can be filled with a filling paste. The filling paste can be a dielectric material (e.g., epoxy, etc.), a conductive material (e.g., copper, silver, etc.), or any other applicable material. For example, the through-hole via 180a (or the plated through-hole via 180A) may be filled with the filling paste, e.g., to enhance the thermal conductivity of the through-hole via 180a (or the plated through-hole via 180A). Additionally, or alternatively, the blind via 180b (or the plated blind via 180B) may be filled with the filling paste (e.g., epoxy, copper, etc.). Such via filling may allow for enhanced heat dissipation with the PCB 100.

In some embodiments, the first insulating layer 130, the second insulating layer 140, and the third insulating layer 160 can be respectively made of a dielectric material. In some embodiments, the first protective layer 110A and the second protective layer 110B can be respectively made of a polymer material (e.g., epoxy). The first protective layer 110A can be disposed on the first insulating layer 130 via a printing process, such as silkscreen printing. In some embodiments, the first protective layer 110A (or the second protective layer 110B) may or may not be flat. As a non-limiting example, as shown in FIG. 1, the first surface conductive layer 120A can be disposed on the first insulating layer 130 and can include one or more conductive elements. The one or more conductive elements can include, for instance, one or more conductive traces (e.g., 1201a and/or 1201b) and upper end(s) of one or more plated vias (e.g., 180A and/or 180B). The one or more conductive elements can be fully or partially connected to each other. For instance, an upper end (see end “A” in FIG. 1) of the plated through-hole via 180A may include a ring structure made of a conductive material (e.g., copper, etc.) and may be connected (e.g., physically and electrically) to a first conductive trace 1201a. For instance, the upper end “A” of the plated through-hole via 180A may or may not be connected to a second conductive trace 1201b.

Continuing with the non-limiting example above, the first protective layer 110A can be disposed on the first surface conductive layer 120A to cover the one or more conductive traces (e.g., 1201a, 1201b), upper ends of one or more vias (plated or not plated), and a portion of the first insulating layer 130 that is not covered by the first surface conductive layer 120A.

In some embodiments, the PCB 100 can include other components, such as one or more buried vias, one or more via-in-pads, or any other applicable component(s). Descriptions of the PCB 100 above are not intended to be limiting. For example, the structure, the total number of layers, the number of different layers, the material(s) and/or process(es) forming different components or layers of the PCB 100 are not limited to the descriptions of the present disclosure.

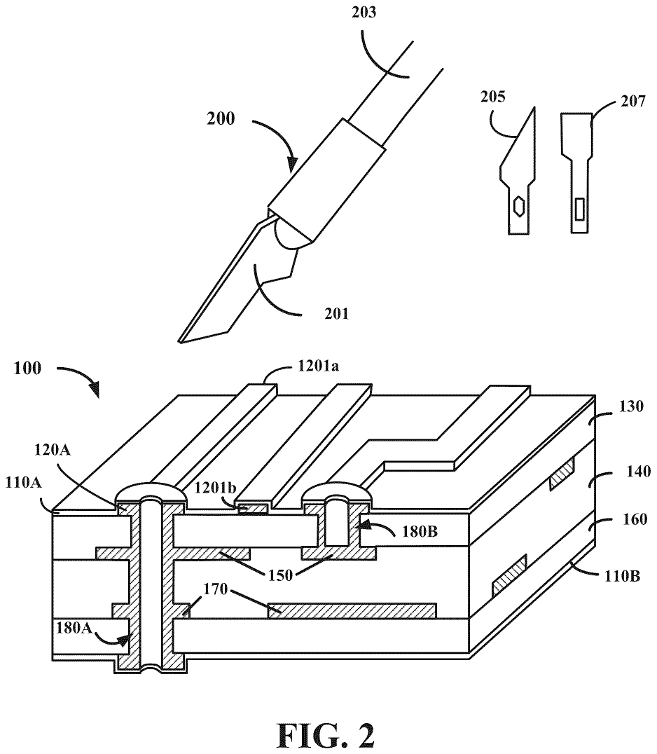

FIG. 2 illustrates a scenario where a precision knife 200 is applied to modify a conductive trace of the example PCB 100 in FIG. 1. As shown in FIG. 2, the precision knife 200 can include a blade 201 and a handle portion 203. The blade 201 can be attached to the handle portion 203. The blade 201 can be configured to, for instance, remove a portion of the first surface conductive layer 120A (or the second surface conductive layer 120B) that covers a conductive trace 1201a (or other conductive element) of the first surface conductive layer 120A, to expose at least a portion of the first conductive trace 1201a. The blade 201 can be further configured to cut the first conductive trace 1201a. The blade 201, for instance, can be removably detached from the handle portion 203. Depending on a width of the first conductive trace 1201a or dimensions of other to-be-exposed component (e.g., plated via 180A) of the PCB 100, an alternative blade 205 or 207 can be selected and applied. The alternative blade 205 (or 207) can have a different shape, and/or different dimensions than the blade 201.

When compared to a width (e.g., 8-10 mils) of a conductive trace (e.g., the first conductive trace 1201a), the blade 201 (or the alternative blade 205 or 207) often has a relatively large size (e.g., a length of approximately 0.5-1 inch, a width of approximately 0.2-0.3 inch, and a thickness of approximately 0.02 inch). Given the relatively large size and given the existing configuration of the blade 201 (or the alternative blade 205 or 207), a user of the precision knife 200 often needs to hold the precision knife 200 in an angled position, in order to remove desired substance (e.g., a desired portion of the first protective layer 110A and/or a desired portion of the first surface conductive layer 120A) from the PCB 100. Without sufficient experience in modifying or testing PCBs, the user, when using the precision knife 200 to remove substance(s) from the PCB 100, can easily cause undesired damage to the PCB 100. The undesired damage can often be irreversible, and can be, but is not necessarily limited to be, a cut of an additional conductive trace (e.g., 1201b) that is adjacent to the conductive trace (e.g., 1201a) which is to be exposed or cut.

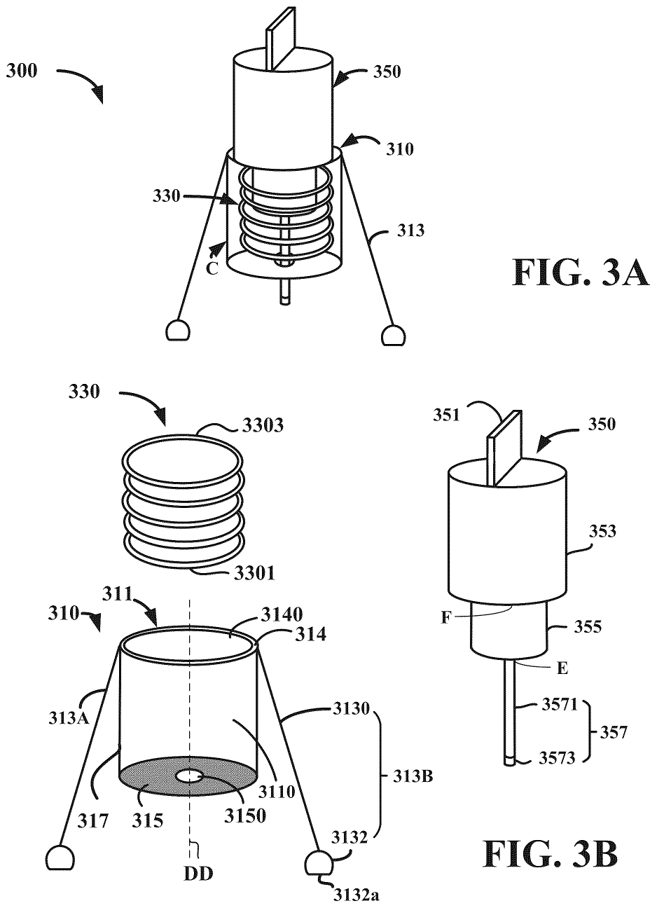

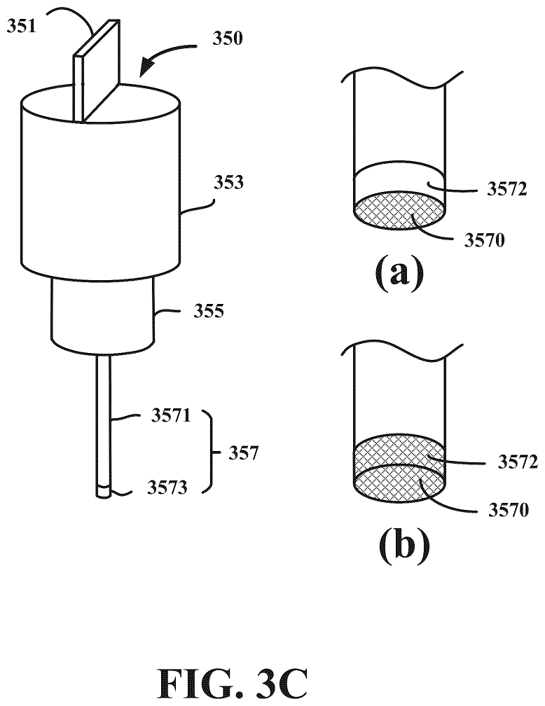

FIG. 3A illustrates an example removal apparatus 300, according to one or more embodiments of the present disclosure. FIG. 3B illustrates an exploded view of the example removal apparatus in FIG. 3A, according to one or more embodiments of the present disclosure. As shown in FIG. 3A and FIG. 3B, in various embodiments, the example removal apparatus 300 can include a support member 310, a spring member 330, and/or a substance-removing member 350. In some embodiments, the support member 310 can include a support body 311 and one or more support legs 313 (e.g., a first support 313A and a second support leg 313B).

In some embodiments, the support body 311 can include a columnar structure C having a bottom portion 315 and a side wall portion 317 protruding from a periphery of the bottom portion 315. For example, the side wall portion 317 can be connected to (e.g., integrated with) the bottom portion 315 and can include an outer side wall and an inner side wall. The inner side wall of the side wall portion 317 of the support body 311 and the bottom portion 315 of the support body 311 can form an accommodating cavity 3110 to accommodate the spring member 330 and/or the substance-removing member 350 (or a portion thereof). In some embodiments, the one or more support legs 313 (e.g., 313A and/or 313B) may be attached to (e.g., fixedly attached to, or slidably attached to) an upper portion of the outer side wall of the side wall portion 317. In some other embodiments, the one or more support legs 313 can be attached to a middle portion or a lower portion of the outer side wall of the side wall portion 317 of the support body 311, depending on an angle formed between a respective support leg (e.g., 313A or 313B) and an axis of the support body 311 (see axis “DD” in FIG. 3B). In some embodiments, the one or more support legs 313 may or may not be evenly attached to the side wall portion 317. In some embodiments, the bottom portion 315 of the columnar structure A can include a through-hole 3150 that penetrates through the bottom portion 315. A diameter of the through-hole 3150 may be less than a diameter of the spring member 330 for the accommodating cavity 3110 to hold or accommodate the spring member 330.

In some embodiments, as shown in FIG. 3B, the columnar structure C can include a top cover 314, and the top cover 314 of the columnar structure C defines an opening 3140 of the support body 311 (or the columnar structure C). The top cover 314 can be an annular plate or can have any other applicable shape or structure. In some other embodiments, as shown in FIG. 3A, the columnar structure C can include the opening 3140 defined by the side wall portion 317, without having the top cover 314. In some embodiments, the opening 3140 of the support body 311 can be so shaped for the spring member 330 (and substance-removing member 350, or a lower portion of the substance-removing member 350) to be inserted into the accommodating cavity 3110. For instance, a diameter of the opening 3140 may be greater than a diameter of the spring member 330, for the spring member 330 to enter into the accommodating cavity 3110. In some embodiments, the columnar structure A is a hollow structure to hold (and/or secure) the spring member 330. For example, a lower portion (e.g., first end 3301) of the spring member 330 that faces the bottom portion 315 of the support body 311 can be fixedly (or removably) attached to a fixing mechanism (not depicted) on the bottom portion 315 so that the spring member 330 is secured.

In some embodiments, a diameter of the opening 3140 of the columnar structure C is approximately the same as a diameter of the bottom portion 315 of the columnar structure C. In some embodiments, a diameter of the opening 3140 of the columnar structure C is greater than the diameter of the bottom portion 315 of the columnar structure C.

In some embodiments, the spring member 330 is configured to support the substance-removing member 350. For example, the spring member 330 can be configured to support movement of the substance-removing member 350 along an axial direction (or an axis) of the columnar structure C, as indicated by dashed line “DD” in FIG. 3B. More detailed descriptions are provided later in this specification.

As a non-limiting example, referring to FIG. 3B, the support member 310 can include two support legs 313A and 313B, where each of the two support legs can include a first leg portion 3130 and a second leg portion 3132. The first leg portion 3130 can be, for instance, a stick (e.g., a plastic stick or a steel stick). The second leg portion 3132 can be, for instance, a ball-shaped base having a flat bottom surface 3132a. The flat bottom surface 3132a of the second leg portion 3132 of the support leg 313A and the flat bottom surface 3132a of the second leg portion 3132 of the support leg 313B, can enable the removal apparatus 300 to stably stand on a PCB board (e.g., the PCB 100). It will be understood that more than two support legs (e.g., three support legs) can be provided in certain embodiments.

Continuing with the non-limiting example above, the spring member 330 can include a coiled spring having a plurality of turns. The spring member 330 can include a first end 3301 and a second end 3303, where the first end 3301 of the spring member 330 can push against the bottom portion 315 of the support body 311. In some embodiments, the first end 3301 can be secured to the bottom portion 315 of the columnar structure C, but this is not required. For example, the first end 3301 of the spring member 330 can be secured to an inner surface of the bottom portion 315 of the columnar structure C that faces the opening 3140. In another example, the first end 3301 of the spring member 330 can be removably attached to the inner surface of the bottom portion 315 of the columnar structure C that faces the opening 3140. In yet another example, the support body 311 is configured to hold the spring member 330, so that the first end 3301 of the spring member 330 is in physical contact with the inner surface of the bottom portion 315 of the support body 311 that faces the opening 3140 of the support body 311. While the spring member 330 is shown in FIG. 3A and FIG. 3B as a coiled spring, the spring member 330 may be implemented by any other suitable mechanism or structure. For example, an air cylinder may be used in place of the spring member 330.

Continuing with the non-limiting example above, the substance-removing member 350 can include a handle portion 351 (also referred to as an “upper handle), a first shaft portion 353, and a second shaft portion 355. The first shaft portion 353 can be disposed on the second shaft portion 355, and the handle portion 351 can be disposed on the first shaft portion 353. For instance, a bottom surface of the first shaft portion 353 can be fixedly connected to an upper surface of the second shaft portion 355, and a bottom surface of the handle portion 351 (“upper handle”) can be fixedly connected to an upper surface of the first shaft portion 353. The upper surface of the first shaft portion 353 can be opposite to the bottom surface of the first shaft potion 353. In some embodiments, the handle portion 351 can be integrated with the first shaft portion 353, and/or the first shaft portion 353 can be integrated with the second shaft portion 355.

In some embodiments, the handle portion 351 (“upper handle”) can be a block, where a length of a bottom surface of the block is equal to or less than a diameter of upper surface of the first shaft portion 355. In some other embodiments, the handle portion 351 can be of any applicable shape, dimension, or structure, to facilitate handling (e.g., holding) by a user of the removal apparatus 300. For example, the handle portion 351 can include multiple components with a size or shape that fits handling by human hand, robot hand, etc. In various embodiments, the substance-removing member 350 can further include a substance-removing assembly 357. The substance-removing assembly 357 can include a body portion 3571 and/or a substance-removing head 3573. The substance-removing head 3573 can be, for instance, a grinding head made of one or more abrasive materials. The substance-removing head 3573 can be attached to or integrated with the body portion 3571, so that rotation of the body portion 3571 causes the substance-removing head 3573 to rotate. In some embodiments, the substance-removing assembly 357 can be fixedly connected to, or integrated with, a bottom surface of the second shaft portion 355. In some other embodiments, the substance-removing assembly 357 can be removably attached to a bottom portion (or the bottom surface) of the second shaft portion 355. For example, the bottom portion of the second shaft portion 355 can be recessed to include a concave portion for securing or engaging the body portion 3571 of the substance-removing assembly 357.

In some embodiments, the spring member 330 can be configured to support the first shaft portion 353 of the substance-removing member 350. For example, a diameter of the first shaft portion 353 of the substance-removing member 350 can be greater than a diameter of the spring member 330, so that the first shaft portion 353 sits above and abuts the spring member 330. In this way, pressing the handle portion 351 (“upper handle”) towards the bottom portion 315 of the support body 311 can cause the spring member 330 to be compressed and a position of the substance-removing assembly 357 to be lowered, e.g., to approximately reach (or be lower than) a plane defined by the flat bottom surface of the one or more support legs 313. The second shaft portion 355 and/or the substance-removing assembly 357 can be configured to enter the hollow columnar structure C of the support member 310, and pass through spring member 330 (or at least a portion thereof when the removal apparatus 300 is not under use). In some embodiments, the second shaft portion 355 and/or the substance-removing assembly 357 may, or may not, further pass through the through-hole 3150 of the bottom portion 315 of the columnar structure C when the removal apparatus 300 is not in use.

A user of the removal apparatus 300 (or a driving unit attached to the removal apparatus 300) can apply a force to (e.g., by pressing) the handle portion 351 so that the substance-removing head 3573 moves down (or protrude from the support body 311 of the support member 310 through the through-hole 3150) along the direction DD, e.g., to get in contact with a target area (sometime referred to as “to-be-exposed area,” “to-be-removed portion,” “to-be-removed area,” “to-be-tested area,” etc.) with material or substance to be removed. The configuration of the spring member 330 allows control of a distance that the substance-removing head 3573 moves under the applied force, and allows the substance-removing head 3573 to retract and therefore no longer be in contact with the target area once the applied force is no longer applied.

In some embodiments, when the substance-removing head 3573 is in contact with the target area, the user (or the driving unit) may rotate the handle portion 351 to force the substance-removing head 3573 to rotate, thereby removing material or substance as desired. After use (e.g., when no force is applied to the removal apparatus 300), the spring member 330 can be configured to support the substance-removing member 350 to move back/be restored to an original position/status.

In some embodiments, the spring member 330 can be omitted, and the first shaft portion 353 and/or the second shaft portion 355 may include a spring mechanism/member that works the same as, or similar to, the spring member 330.

FIG. 3C illustrates two non-limiting examples of substance-removing head for the example removal apparatus in FIG. 3A, according to one or more embodiments of the present disclosure. As shown in FIG. 3C, the substance-removing head 3573 can include a bottom wall 3570 and a side wall 3572. As a non-limiting example (a) shown in FIG. 3C, the bottom wall 3570 can be made of an abrasive material, and the side wall 3572 can be made of a non-abrasive material. As another non-limiting example (b) shown in FIG. 3C, the bottom wall 3570 can be made of a first abrasive material, and the side wall 3572 can be made of a second abrasive material. The second abrasive material can be the same as, or different from, the first abrasive material. For instance, the substance-removing head 3573 can have a columnar shape and can be made entirely of an abrasive material, such as a steel, a ceramic, a composite material, or any combination thereof.

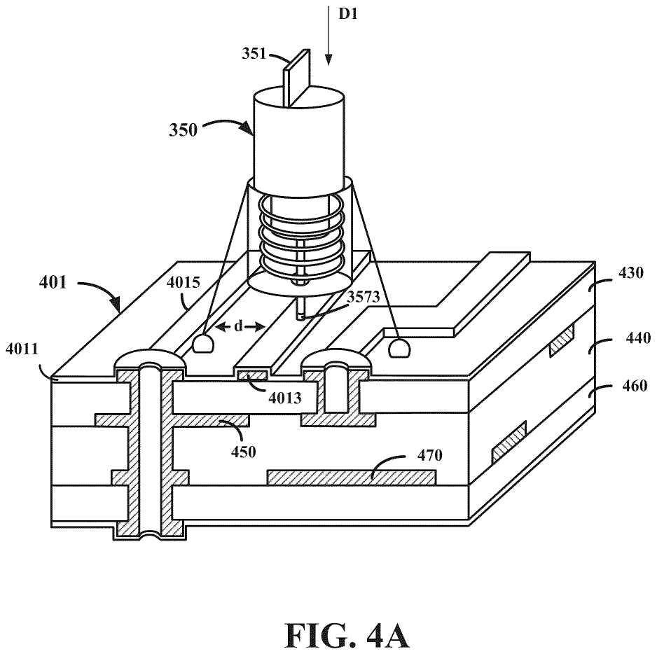

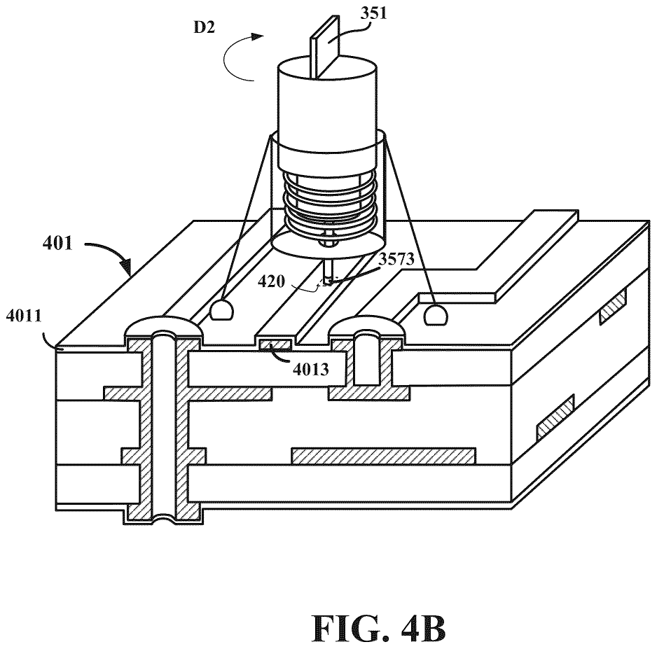

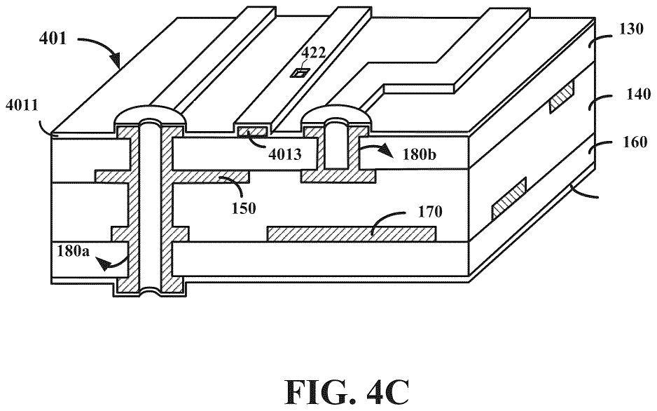

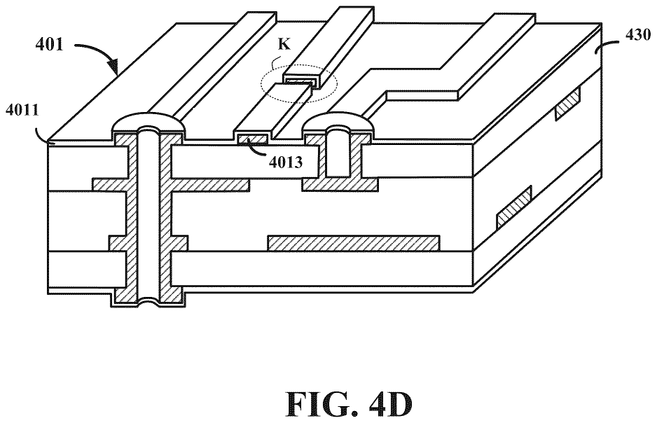

FIG. 4A illustrates a scenario where an example removal apparatus is placed with respect to (e.g., in a proximate to) a conductive trace of a PCB 401, according to one or more embodiments of the present disclosure. FIG. 4B illustrates a status of the example removal apparatus where under an applied force, a substance-removing head of the example removal apparatus is in contact with a to-be-removed portion of the PCB that covers a to-be-tested area of the conductive trace in FIG. 4A. FIG. 4C illustrates exposure of the to-be-tested area of the conductive trace in FIG. 4B, according to one or more embodiments of the present disclosure. FIG. 4D illustrates a scenario where the conductive trace of the PCB in FIG. 4C is cut using the example removal apparatus, according to one or more embodiments of the present disclosure.

As shown in FIG. 4A, a PCB 401 can include a plurality of conductive traces for carrying electrical signal(s), where the plurality of conductive traces are covered using a protective layer 4011. In some embodiments, the plurality of conductive traces can include a conductive trace 4013. In some embodiments, the plurality of conductive traces can include an additional conductive trace 4015, where the additional conductive trace 4015 is adjacent to, or otherwise close to, the conductive trace 4013.

As a non-limiting example, a spacing (“d”) between the conductive trace 4013 and the additional conductive trace 4015 may be approximately 4-10 mils. A user may want to test a condition of the conductive trace 4013. In this case, a portion of the protective layer 4011 covering the conductive trace 4013 needs to be removed, so as to expose a to-be-tested area (see “422” in FIG. 4C, sometimes also referred to as “to-be-exposed area”, etc.) of the conductive trace 4013 for electrical test(s). Using the precision knife depicted in FIG. 2 to remove the portion of the protective layer 4011 as desired requires precise human control of the precision knife, which can be a challenge for maintenance staff or other user(s) that have insufficient relevant experience. Failure to exercise the precise human control can result in irreversible damage to the PCB 401 itself, e.g., damage to the additional conductive trace 4015 (if present within the PCB 401) which is hard or impossible to repair. By contrast, the removal apparatus 300 can enable a user having insufficient relevant experience to more precisely remove the portion(s) of the protective layer 4011 as desired.

As shown in FIG. 4A, a user of the removal apparatus 300 can place the removal apparatus 300 on the PCB 401 in a way where the substance-removing head 3573 is placed above the to-be-tested area of the conductive trace 4013 (which is covered by a to-be-removed portion of the protective layer 4011, see “420” in FIG. 4B). In some embodiments, the user of the removal apparatus 300 can place the removal apparatus 300 on the PCB 401 in a way where the substance-removing head 3573 aligns with the to-be-tested area of the conductive trace 4013. For example, the user of the removal apparatus 300 can place the removal apparatus 300 in a manner where a center point of a bottom wall of the substance-removing head 3573 aligns with a center point of the to-be-tested area. In some embodiments, the flat bottom surface 3132a of the second leg portion 3132 of the support leg 313A and the flat bottom surface 3132a of the second leg portion 3132 of the support leg 313B, can each be made of (or covered by) an insulating material (e.g., plastic such as fiberglass). By covering the flat bottom surfaces of the support legs (e.g. 313A and 313 B) with an insulating material, there is no need to determine specific area(s) of the PCB to place the support legs (e.g. 313A and 313 B) of the removal apparatus 300, so that the risks such as short circuit can be avoided or reduced.

In cases where there is a region of conductive material exposed (e.g., not covered by the protective layer 4011 or other insulating material/layer) near the conductive trace 4013, the user of the removal apparatus 300 can still determine appropriate locations to place the support legs of the removal apparatus 300 so as to approximately align the center point of the bottom wall (e.g., 3570) of the substance-removing head 3573 with the center point of the to-be-tested area of the conductive trace 4013.

In some embodiments, referring to FIG. 4A˜FIG. 4C, after the substance-removing head 3573 is placed above (and aligns with) the to-be-tested area of the conductive trace 4013, the user of the removal apparatus 300 can hold the handle portion 351 of the removal apparatus 300. The user can apply a small force (e.g., in a vertical direction D1 as indicated by the arrow in FIG. 4A) to the handle portion 351 to push the substance-removing member 350 towards the to-be-tested area (e.g., “422” in FIG. 4C) of the conductive trace 4013 (which is covered by the to-be-removed portion “420” of the protective layer 4011). During this process, the spring member 330 can be deformed to provide a buffering function, which prevents harsh contact between the substance-removing head 3573 and the to-be-removed portion 420 of the protective layer 4011. Once the substance-removing head 3573 of the substance-removing member 350 touches the to-be-removed portion 420 of the protective layer 4011 that covers the to-be-tested area 422, the user can rotate the handle portion 351 (or cause rotation of the handle portion 351, see direction D2 indicated by an arrow in FIG. 4B) to force rotation of the substance-removing head 3573, so as to remove the to-be-removed portion 420 of the protective layer 4011. The removal of the to-be-removed portion 420 of the protective layer 4011 then enables the to-be-tested area 422 of the conductive trace 4013 to be exposed for electrical test(s), e.g., using a probe of an oscilloscope. While the shape of the to-be-removed portion 420 or the shape of the to-be-tested area 422 are illustrated in the figures as a square, the removal apparatus 300 can be utilized to create any applicable shape for the to-be-removed portion 420 or the to-be-tested area 422, such as rectangular, circle, annular, or other regular or irregular shapes. A depth or thickness of material(s) or substance(s) removed by the substance-removing head 3572 can also be controlled using the disclosed removal apparatus 300.

In some embodiments, the user of the removal apparatus 300 may want to modify (e.g., cut) the to-be-tested area 422 of the conductive trace 4013, or to modify a to-be-modified area of the conductive trace 4013 (or the additional conductive trace 4015), etc. For example, referring to FIG. 4D, the user of the removal apparatus 300 may want to cut the conductive trace 4013 after the to-be-removed portion 420 of the protective layer 4011 is removed. In this case, the user of the removal apparatus 300 can push the substance-removing member 350 towards the to-be-tested area 422 (or a to-be-cut portion indicated by dashed circle “K” in FIG. 4D) of the conductive trace 4013, which has been exposed already. Once the substance-removing head 3573 of the substance-removing member 350 touches the to-be-tested area 422 (or the to-be-cut portion) of the conductive trace 4013, the user can rotate the handle portion 351 to force rotation of the substance-removing head 3573, so as to remove conductive material (e.g., copper) below or associated with the to-be-tested area 422 (or the to-be-cut portion) of the conductive trace 4013, thereby modifying or cutting the conductive trace 4013. During the modifying or cutting process, the removal apparatus may be moved, e.g., to cut off the conductive trace 4013. In some embodiments, a diameter (or other dimensions) of the substance-removing head 3573 can be selected based on one or more dimensions of the conductive trace 4013 (or other conductive element). For example, to cut a conductive trace (e.g., 4013) having a width of approximately 4 mils, a substance-removing assembly 357 with a substance-removing head having a diameter of approximately 4 mils can be selected from a plurality of substance-removing assemblies each having a substance-removing head of a varying diameter, for attachment to the second shaft portion 355 of the substance-removing member 350. Such selected substance-removing assembly 357 with the substance-removing head having a diameter of approximately 4 mils can then be applied to cut the conductive trace having the width of approximately 4 mils, to reduce the turns of rotating the substance-removing head and/or to reduce movement of the removal apparatus 300 over the PCB 401.

In some embodiments, the support member 310 can be made of a rigid material (e.g., steel). In some embodiments, a flat bottom surface/wall 3132a of a second leg portion 3132 of a support leg (e.g., 313A or 313B) can be made of an insulating material (e.g., plastic such as fiberglass). In some embodiments, the spring member 330 can be made of carbon steel. In some embodiments, the handle portion 351, the first shaft portion 353, and/or the second shaft portion 355 can be made of plastic. In some embodiments, the substance-removing assembly 357 or a portion thereof can be made of a steel. Descriptions of the material(s) of each component (e.g., 310, 330, 350, etc.), however, are not limited herein.

By using the removal apparatus 300 of the present disclosure, a user can precisely remove a target component (e.g., the to-be-removed portion 420 of the protective layer 4011) of the PCB (e.g., 401), without damaging an adjacent component that is adjacent to the target component or damaging an internal structure (e.g., one or more inner layers) of the PCB (e.g., 401). This prevents causing irreversible damages to the PCB, and allows a user with insufficient experience to confidently test or modify the PCB. The apparatus and systems of the present disclosure cost relatively low to manufacture, are easy to assemble and convenient to use, and facilitate users of PCBs to perform electrical testing and circuit modification during the development and testing stages of PCBs.

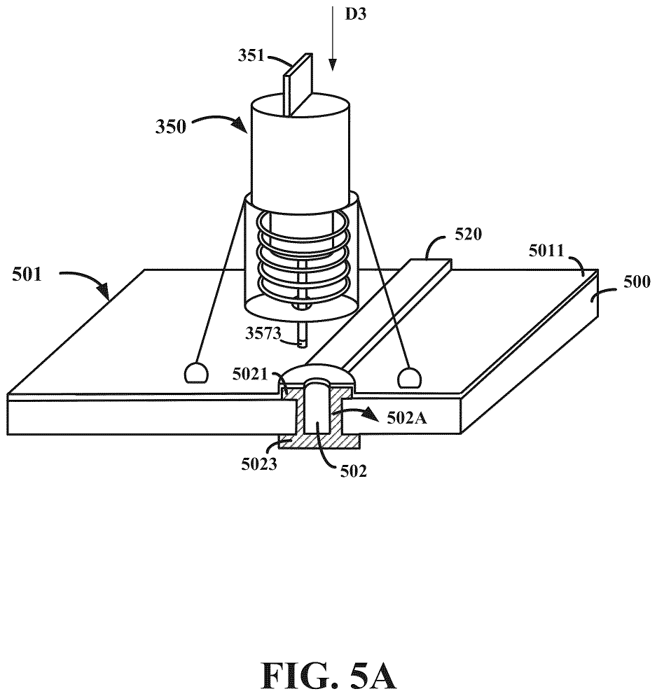

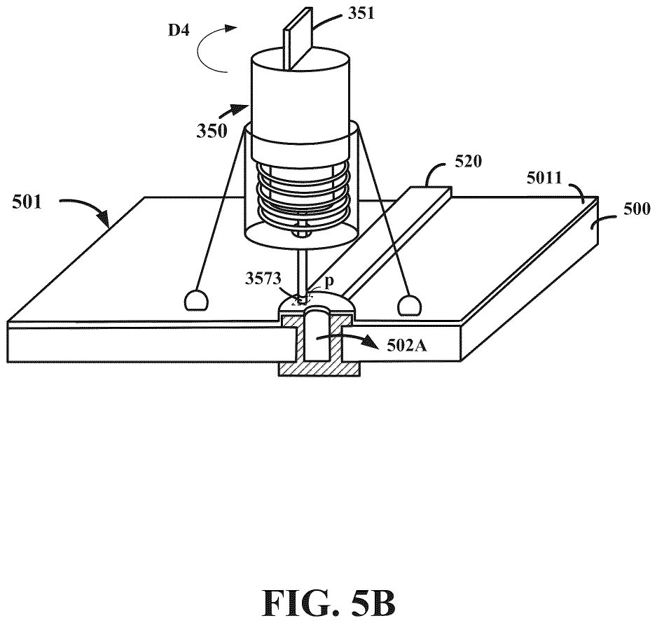

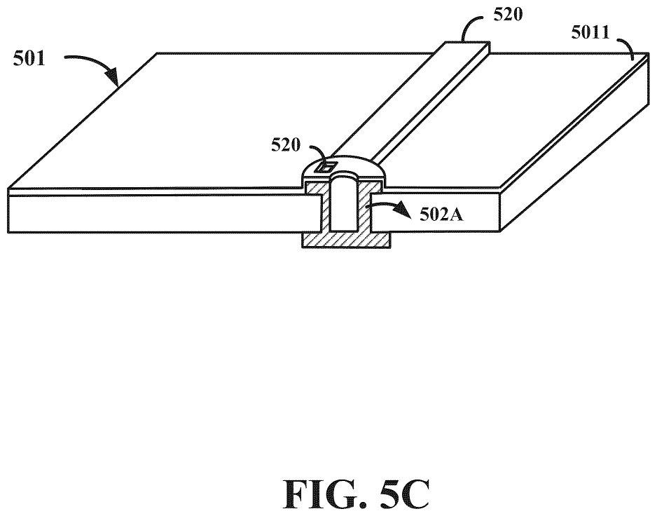

FIG. 5A illustrates a scenario where an example removal apparatus is placed with respect to a via (e.g., a plated via) of a PCB 501, according to one or more embodiments of the present disclosure. FIG. 5B illustrates a status of the example removal apparatus where a substance-removing head of the example removal apparatus is in contact with a to-be-removed portion of the PCB that covers a to-be-tested area of the plated via in FIG. 5A. FIG. 5C illustrates exposure of the to-be-tested area of the plated via in FIG. 5B, according to one or more embodiments of the present disclosure.

As shown in FIG. 5A, the PCB 501 can include a vias 502, where an inner side wall of the via 502 is plated with a conductive material to form a plated via 502A for electrically connecting one conductive layer of the PCB 501 to another. The via 502 is covered using a protective layer 5011. The plated via 502A may be electrically connected to a conductive trace 520 (which is disposed on an insulating layer 500 and covered by the protective layer 5011). But this is not required. In some embodiment, the plated via 502A can include a top plated surface 5021 and a bottom plated surface 5023. A user of the removal apparatus 300 can determine a to-be-exposed area of the top plated surface 5021 (or the bottom plated surface 5023) of the plated via 502A, and place the removal apparatus 300 with respect to the to-be-exposed area of the top plated surface 5021 (or the bottom plated surface 5023) of the plated via 502A.

In some embodiments, the user of the removal apparatus 300 can place the removal apparatus 300 on the PCB 501 in a way where the substance-removing head 3573 is placed above the to-be-exposed area of the plated via 502A (which is covered by a to-be-removed portion “P” of the protective layer 5011 that is to be removed, see “P” in FIG. 5B). In some embodiments, the user of the removal apparatus 300 can place the removal apparatus 300 on the PCB 401 in a way where the substance-removing head 3573 aligns with the to-be-removed portion “P” of the protective layer 5011 that is to be removed. For example, as shown in FIG. 5B, the user of the removal apparatus 300 can place the removal apparatus 300 in a manner where a center point of the bottom wall of the substance-removing head 3573 aligns with a center point of the to-be-removed portion “P” of the protective layer 5011. In some embodiments, the flat bottom surface of the second leg portions of the support legs of the removal apparatus 300 can each be made of an insulating material (e.g., plastic such as fiberglass), to avoid short circuits.

In some embodiments, after the substance-removing head 3573 is placed above (and aligns with) the to-be-removed portion “P” of the protective layer 5011 that covers the to-be-exposed area (e.g., “520” in FIG. 5C) of the plated via 502A, the user of the removal apparatus 300 can hold the handle portion 351 of the removal apparatus 300. The user can apply a small force (e.g., see an arrow D3 pointing vertically in FIG. 5A) to the handle portion 351 to push the substance-removing member 350 towards the to-be-exposed area of the plated via 502A, which is covered by the to-be-removed portion of the protective layer 5011. Once the substance-removing head 3573 of the substance-removing member 350 touches the to-be-removed portion of the protective layer 5011, the user can rotate (see the rotation arrow “D4” in FIG. 5B) the handle portion 351 to force rotation of the substance-removing head 3573, so as to remove the to-be-removed portion (“P”) of the protective layer 5011. The removal of the to-be-removed portion of the protective layer 5011 then enables the to-be-exposed area (“520” in FIG. 5C) of the plated via 502A to be exposed for electrical test(s). In some embodiments, as shown in FIG. 5A˜5C, the plated via 502A is a through-hole via plated with a conductive material (e.g., copper). In some embodiments, the plated via 502 is a blind via plated with a conductive material. A plated blind via can be exposed using the removal apparatus 300 in a similar way, and repeated descriptions are omitted herein for the sake of brevity.

It is noted that, while the foregoing descriptions provide applying the removal apparatus 300 to remove substances so as to expose or cut conductive traces or vias, the removal apparatus 300 of the present disclosure can be applied to expose, cut, or modify other conductive element(s) which may be (but do not necessarily need to be) from PCB(s).

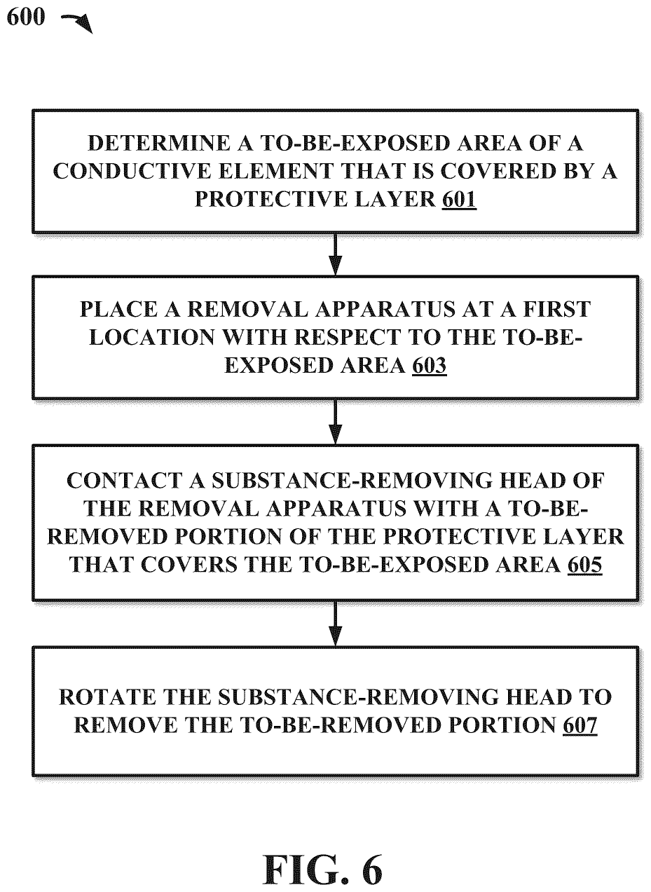

FIG. 6 illustrates a method 600 for exposing and/or modifying an element (e.g., a conductive trace) of a PCB, using an example removal apparatus, according to one or more embodiments of the present disclosure. A system for performing the method 600 can include the example removal apparatus (e.g., 300 in FIG. 4A). In some embodiments, the system may further include a driving unit (e.g., a motor) that drives movement or operation of the removal apparatus. In some embodiments, the system may further include one or more processors to execute instructions that define movement or operation (e.g., one or more forces applied to) of the removal apparatus. In various embodiments, as shown in FIG. 6, at stage 601, the system determines a to-be-exposed area of a conductive element. The conductive element can be a conductive trace of a printed circuit board (PCB), a via having an inner wall plated with a conductive material, or any other applicable conductive element. The to-be-exposed area of the conductive element is covered using a protective layer, to prevent oxidation, etc. The conductive element can be disposed, for instance, on an insulating layer of the PCB (e.g., see FIG. 4A or 5A).

In various embodiments, as shown in FIG. 6, at stage 603, the system can place a removal apparatus (e.g., at a first location) with respect to the to-be-exposed area of the conductive element. A non-limiting example of the removal apparatus is provided in FIG. 3A and FIG. 3B. In this non-limiting example, the removal apparatus can include a support member, a spring member, and/or a substance-removing member. The substance-removing member can include a handle portion (“upper handle”), a first shaft portion, and a second shaft portion. The first shaft portion can be arranged to connect the second shaft portion with the handle portion. For instance, a bottom surface of the first shaft portion can be fixed to an upper surface of the second shaft portion, and a bottom surface of the handle portion can be fixed to an upper surface of the first shaft portion.

In some embodiments, the substance-removing member can further include a substance-removing assembly attached (e.g., fixed) to the second shaft portion. The substance-removing assembly can include a body portion and/or a substance-removing head. The body portion of the substance-removing assembly can be attached (e.g., fixedly connected) to the second shaft portion. The substance-removing head can be, for instance, a grinding head made of one or more abrasive materials. In some embodiments, the substance-removing assembly can be fixed to a bottom surface of the second shaft portion. In some other embodiments, the substance-removing assembly can be removably attached to a bottom portion of the second shaft portion. For example, the bottom portion of the second shaft portion can include a concave portion for securing or engaging the body portion of the substance-removing assembly.

The support member can include a support body and two or more support legs, where each support leg can include a first leg portion and a second leg portion. The first leg portion can be, for instance, a stick. The second leg portion can be, for instance, a ball-shaped base having a flat bottom surface. In some embodiments, the support body can include a columnar structure, where a bottom portion of the columnar structure can include a through-hole allowing the body portion of the substance-removing assembly of the substance-removing member to pass through. A top portion of the columnar structure of the support body can include an opening (or a top cover defining an opening) for insertion of the substance-removing member.

The spring member can include a coiled spring having a plurality of turns. The spring member can include a first end and a second end, where the first end of the spring member can push against the bottom portion of the support body. In some embodiments, the first end of the spring member can be secured to the bottom portion of the columnar structure, but this is not required. While the spring member is shown in FIG. 3A and FIG. 3B as a coiled spring, the spring member may be implemented by any other suitable mechanism or structure. In some embodiments, a diameter of the spring member can be greater than a diameter of the second shaft portion of the substance-removing member, and the diameter of the spring member can be less than a diameter of the first shaft portion of the substance-removing member. Such configuration of the diameters allows the second shaft portion of the substance-removing member to pass through the spring member while blocking the passing through of the first shaft portion of the substance-removing member. As a result, a force applied to the handle portion of the substance-removing member (e.g., in a vertical direction) may gently push the substance-removing head of the substance-removing member to contact a target component (or a target area) of the PCB to be removed, with the spring member providing a buffering function.

In various embodiments, as shown in FIG. 6, at stage 605, the system causes a substance-removing head of the removal apparatus to be in contact with a to-be-removed portion of the protective layer that covers the to-be-exposed area of the conductive element. For example, a first force can be applied to the removal apparatus to push the substance-removing head of the removal apparatus towards the to-be-exposed area of the conductive element (e.g., conductive trace). In some embodiments, the substance-removing head of the removal apparatus can be selected from a plurality of replaceable substance-removing heads of the removal apparatus. Selection of the substance-removing head can be based on one or more dimensions of the to-be-exposed area of the conductive element. For example, the substance-removing head can be selected based on a width of the conductive trace.

In various embodiments, as shown in FIG. 6, at stage 607, the system can cause the substance-removing head to rotate, thereby removing the to-be-removed portion of the protective layer that covers the to-be-exposed area of the conductive element. For example, in response to the substance-removing head of the removal apparatus being in contact with the to-be-removed area of the protective layer that covers the to-be-exposed area of the conductive element, a second force is applied to the removal apparatus to rotate the substance-removing head of the removal apparatus, thereby removing the to-be-removed area of the protective layer, which exposes the to-be-exposed area of the conductive element. A direction of the first force and a direction of the second force can be different. The exposure of the to-be-exposed area of the conductive element allows electrical tests to determine whether such conductive element carries a normal signal.

In some embodiments, the conductive element is a conductive trace. In this case, the system can further rotate the substance-removing head of the removal apparatus, to cut the conductive trace. This allows re-wiring or modification of a circuit of the PCB. It is noted that, while the systems and methods are described to expose or modify a conductive element of a PCB, the disclosed systems, apparatus, and methods may also be applied to expose and/or modify a non-conductive element of the PCB, or other elements or components of a structure different from the PCB. For example, the disclosed systems, apparatus, and methods may be applied to remove a portion of a protective layer that covers a via (e.g., not plated with a conductive material but filled with a filling paste), to expose such via. In this example, the disclosed apparatus and methods may be further applied to remove the filling paste (or a portion thereof) that fills the via.

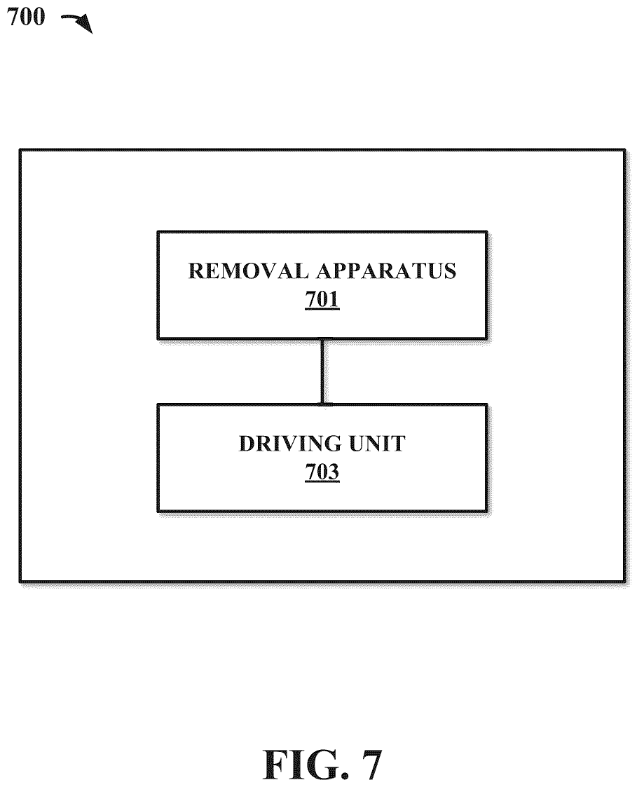

FIG. 7 illustrates an example system 700, according to one or more embodiments of the present disclosure. The system 700 can include a removal apparatus 701 and/or a driving unit 703 (e.g., a driving motor). In various embodiments, the removal apparatus 701 can include: a spring member, a support member to hold the spring member, and a substance-removing member comprising a substance-removing head. A bottom portion of the support member can include a through-hole that allows the substance-removing head to run through.

In some embodiments, the substance-removing member can include a substance-removing assembly, and the substance-removing assembly can include a body portion and a substance-removing head removably attached to the body portion.

In some embodiments, a diameter of the substance-removing head is approximately 2-10 mils.

In some embodiments, the substance-removing member can further include a first shaft portion and a second shaft portion, where a first end (e.g., see “E” in FIG. 3B) of the second shaft portion is connected to the body portion of the substance-removing assembly, and a second end (e.g., see “F” in FIG. 3B) of the second shaft portion that is opposite to the first end is connected to the first shaft portion.

In some embodiments, the substance-removing member further includes an upper handle fixed to the first shaft portion.

In some embodiments, a diameter of the first shaft portion is greater than a diameter of the second shaft portion.

In some embodiments, a diameter of the spring member is greater than a diameter of the second shaft portion, and the diameter of the spring member is less than a diameter of the first shaft portion.

In some embodiments, the removal apparatus further includes: an additional substance-removing head for removably attachment to the body portion of the substance-removing assembly, where a diameter of the additional substance-removing head is different from a diameter of the substance-removing head.

In some embodiments, a dimension of the additional substance-removing head is determined based on an inner diameter and an outer diameter of a via of a printed circuit board (PCB).

In some embodiments, a dimension of the substance-removing head is determined based on a width of a conductive trace of a printed circuit board (PCB).

In some embodiments, the support member includes a support body and a plurality of support legs fixedly attached to the support body. In some embodiments, a base of a support legs from the plurality of support legs includes a flat bottom surface.

In some embodiments, the support body of the support member is hollow and includes a top opening (e.g., opening “3140” in FIG. 3B) for insertion of the substance-removing member. In some embodiments, a diameter of the top opening of the support body is greater than a diameter of a first shaft portion of the substance-removing member.

In some embodiments, the support member is made of a rigid material.

The above descriptions and descriptions of removal apparatus and method or system depicted in various figures of the present disclosure are intended only as a specific example for purposes of illustrating some implementations. Many other configurations of systems and apparatus are possible having more or fewer components than those described above or depicted in the figures. Moreover, while operations of the method 600 are shown in a particular order, this is not meant to be limiting. One or more operations may be reordered, omitted, and/or added.

It's appreciated that different features from different embodiments may be combined with and/or exchanged for one another. In addition, those of ordinary skill in the art will recognize that various changes and modifications of the various implementations described herein can be made without departing from the scope and spirit of the present disclosure. The terms and words used in the descriptions and claims of the present disclosure are not limited to the bibliographical meanings, and are merely used by the inventor to enable a clear and consistent understanding of the present disclosure. Accordingly, it should be apparent to those skilled in the art that the description of various embodiments of the present disclosure is provided for the purpose of illustration only and not for the purpose of limiting the present disclosure as defined by the appended claims and their equivalents.

What is claimed is:

1. A removal apparatus, comprising:
a support member; and
a substance-removing member comprising a substance-removing head,
wherein a bottom portion of the support member comprises a through-hole that allows the substance-removing head to pass through.

2. The removal apparatus of claim 1, wherein:
the substance-removing member comprises a substance-removing assembly, and
the substance-removing assembly comprises a body portion and the substance-removing head removably attached to the body portion.

3. The removal apparatus of claim 2, wherein a diameter of the substance-removing head is approximately 2-10 mils.

4. The removal apparatus of claim 2, wherein:
the substance-removing member further comprises a first shaft portion and a second shaft portion,
a first end of the second shaft portion is connected to the body portion of the substance-removing assembly, and
a second end of the second shaft portion that is opposite to the first end is connected to the first shaft portion.

5. The removal apparatus of claim 4, wherein:
the substance-removing member further comprises an upper handle fixed to the first shaft portion.

6. The removal apparatus of claim 4, wherein:
a diameter of the first shaft portion is greater than a diameter of the second shaft portion.

7. The removal apparatus of claim 4, further comprising a spring member, wherein:
a diameter of the spring member is greater than a diameter of the second shaft portion, and
the diameter of the spring member is less than a diameter of the first shaft portion.

8. The removal apparatus of claim 2, further comprising:
an additional substance-removing head for removably attachment to the body portion of the substance-removing assembly, wherein a diameter of the additional substance-removing head is different from a diameter of the substance-removing head.

9. The removal apparatus of claim 8, wherein:
a dimension of the additional substance-removing head is determined based on an inner diameter and an outer diameter of a via of a printed circuit board (PCB).

10. The removal apparatus of claim 2, wherein:
a dimension of the substance-removing head is determined based on a width of a conductive trace of a printed circuit board (PCB).

11. The removal apparatus of claim 1, wherein:
the support member comprises a support body and a plurality of support legs fixedly attached to the support body.

12. The removal apparatus of claim 11, wherein a base of a support leg from the plurality of support legs comprises a flat bottom surface.

13. The removal apparatus of claim 11, wherein the support body of the support member is hollow and comprises an opening for insertion of the substance-removing member.

14. The removal apparatus of claim 13, wherein a diameter of the opening of the support member is greater than a diameter of a first shaft portion of the substance-removing member.

15. The removal apparatus of claim 1, wherein the support member is made of a rigid material.

16. A system, comprising:
a removal apparatus; and
a driving unit to drive the removal apparatus,
wherein the removal apparatus comprises:
a spring member,
a support member to hold the spring member, and
a substance-removing member comprising a substance-removing head,
wherein a bottom portion of the support member comprises a through-hole that allows the substance-removing head to pass through.

17. A method, comprising:
determining a to-be-exposed area of a conductive element of a printed circuit board (PCB), the to-be-exposed area of the conductive element being covered by a protective layer of the PCB;
placing a removal apparatus at a first location with respect to the to-be-exposed area of the conductive element;
contacting a substance-removing head of the removal apparatus with a to-be-removed portion of the protective layer that covers the to-be-exposed area of the conductive element; and
rotating the substance-removing head of the removal apparatus so that the to-be-removed portion of the protective layer is removed to expose the to-be-exposed area of the conductive element.

18. The method of claim 17, wherein the conductive element is a conductive trace, and the method further comprises:
further rotating the substance-removing head of the removal apparatus, thereby cutting the conductive trace.

19. The method of claim 18, wherein further rotating the substance-removing head of the removal apparatus comprises:
placing the removal apparatus at a second location different from the first location,
contacting the substance-removing head of the removal apparatus with an additional to-be-removed portion of the protective layer; and
rotating the substance-removing head of the removal apparatus, thereby removing the additional to-be-removed portion of the protective layer.

20. The method of claim 17, further comprising:
prior to placing the removal apparatus with respect to the to-be-exposed area of the conductive element:
selecting, based on one or more dimensions of the conductive element, the substance-removing head from a plurality of substance-removing heads for the removal apparatus.
